(19) United States
(12) Patent Application Publication
(10) Pub. No.: US 2026/0320258 A1
(43) Pub. Date: Oct. 15, 2026

(54) MODELING SELECTION OF POST COMBUSTION CARBON CAPTURE SORBENTS

(71) Applicant: GE Vernova Infrastructure Technology LLC, Greenville, SC (US)

(72) Inventors: Soumya CHAKRABORTY, Bengaluru (IN); Albert S. STELLA, Schenectady, NY (US); Mohandas NAYAK, Bengaluru (IN); Amit GAIKWAD, Bengaluru (IN)

(21) Appl. No.: 19/485,579

(22) PCT Filed: Jul. 25, 2023
(86) PCT No.: PCT/US2023/028580

§ 371 Date: Nov. 18, 2025

Related U.S. Application Data
(63) Continuation of application No. PCT/US2023/023746, filed on May 26, 2023.

(51) Int. Cl. G06F 30/27; B01D 53/04; B01J 20/22

(52) U.S. Cl. CPC G06F 30/27; B01D 53/0454; B01J 20/226; B01D 2253/204; B01D 2257/504; B01D 2258/0283

(57) ABSTRACT

A method of proposing one or more prospective sorbents, the method performed using a sorbent modeling computing device that includes a processor coupled to a memory device. The method includes generating, using a sorbent modeling framework of the sorbent modeling computing device, an initial set of primary features, and determining, using the sorbent modeling framework, one or more secondary features, wherein the one or more secondary features are combinations of the generated primary features including an interaction parameter. The method also includes subjecting, using the sorbent modeling framework, a feature set of the primary and secondary features to a correlation review, and proposing, using the sorbent modeling framework, a carbon capture performance framework. The method further includes proposing, by the sorbent modeling computing device, one or more prospective sorbents to be used by a post combustion carbon system.

### CROSS-REFERENCE TO RELATED APPLICATIONS

This application claims the benefit of priority to PCT Patent Application Ser. No. PCT/US2023/023746, filed May 26, 2023, and entitled “MACHINE LEARNING MODEL INCORPORATING PHYSICAL FEATURES OF SORBENTS FOR POST COMBUSTION CARBON CAPTURE”, the contents and disclosures of which are hereby incorporated in their entirety.

### TECHNICAL FIELD

The present application relates generally to methods for proposing sorbents, specifically metal organic frameworks, to be used with a post combustion carbon capture system.

### BACKGROUND

Some power plant systems may include post combustion carbon capture (“PCC”) systems that are configured to capture carbon dioxide (CO₂) from the waste gas (flue gas) produced. PCC systems may be used to capture CO₂ from the waste gas produced by power plants that include, for example, coal-burning systems, gas turbines, and/or boilers. Some types of PCC systems use metal-organic frameworks (“MOFs”) to facilitate carbon capture. Metal-organic frameworks typically include two main components, an inorganic metal constituent (often called a secondary building unit, or “SBU”) and an organic constituent (often called a “linker”). Various different MOFs have been developed and tested for their capture capacity (e.g., a measure of how effective a particular MOF performs at capturing CO₂). However, there are potentially millions of combinations of metals, linkers, and other functional groups that could be employed in an MOF, some of which could yield greater capture capacity and productivity than existing MOFs, and the real-world creation and study of each possible combination of constituents is economically prohibitive.

What is needed is a method that combines modeling and chemical knowledge-based methods in order to more effectively propose MOFs for use with a post combustion carbon capture system.

### SUMMARY

In one aspect, a method of proposing one or more prospective sorbents is provided, the method performed using a sorbent modeling computing device that includes a processor coupled to a memory device. The method includes generating, using a sorbent modeling framework of the sorbent modeling computing device, an initial set of primary features, and determining, using the sorbent modeling framework of the sorbent modeling computing device, one or more secondary features, wherein the one or more secondary features are combinations of the generated primary features including an interaction parameter. The method also includes subjecting, using the sorbent modeling framework of the sorbent modeling computing device, a feature set of the primary and secondary features to a correlation review, and proposing, using the sorbent modeling framework of the sorbent modeling computing device, a carbon capture performance framework. The method further includes proposing, by the sorbent modeling computing device, one or more prospective sorbents to be used by a post combustion carbon system.

In another aspect, a sorbent modeling computing device is provided. The sorbent modeling computing device includes a memory and a processor communicatively coupled to the memory. The processor is programmed to generate an initial set of primary features with a sorbent modeling framework and determine one or more secondary features with the sorbent modeling framework, wherein the one or more secondary features are combinations of the generated primary features including an interaction parameter. The processor is also programmed to subject a feature set of the primary and secondary features to a correlation review with the sorbent modeling framework and propose a carbon capture performance framework with the sorbent modeling framework. The processor is further programmed to propose one or more prospective sorbents to be used by a post combustion carbon system.

### BRIEF DESCRIPTION OF THE DRAWINGS

The subject-matter of the disclosure will be explained in more detail in the following text with reference to exemplary embodiments which are illustrated in the attached drawings.

FIG. 1 is an exemplary configuration of a system that can be used to anticipate how particular MOFs may perform in capturing carbon dioxide (CO2) from exhaust gases of a power plant.

FIG. 2 is an exemplary method flow chart in accordance with the present disclosure.

The reference symbols used in the drawings, and their meanings, are listed in summary form in the list of reference symbols. In principle, identical parts are provided with the same reference symbols in the figures.

### DETAILED DESCRIPTION

In the following specification and the claims, reference will be made to a number of terms, which shall be defined to have the following meanings.

As used herein, the singular forms “a,” “an,” and “the” include plural references unless the context clearly dictates otherwise. The terms “comprising,” “including,” and “having” are intended to be inclusive and mean that there may be additional elements other than the listed elements. The terms “optional” or “optionally” means that the subsequently described event or circumstance may or may not occur, and that the description includes instances where the event occurs and instances where it does not.

Unless otherwise indicated, approximating language, such as “generally,” “substantially,” and “about,” as used herein indicates that the term so modified may apply to only an approximate degree, as would be recognized by one of ordinary skill in the art, rather than to an absolute or perfect degree. Accordingly, a value modified by a term or terms, such as “about,” “approximately,” and “substantially,” is not to be limited to the precise value specified. In at least some instances, the approximating language may correspond to the precision of an instrument for measuring the value. Here and throughout the specification and claims, range limitations may be identified. Such ranges may be combined and/or interchanged, and include all the sub-ranges contained therein unless context or language indicates otherwise.

Additionally, unless otherwise indicated, the terms “first,” “second,” etc. are used herein merely as labels, and are not intended to impose ordinal, positional, or hierarchical requirements on the items to which these terms refer. Moreover, reference to, for example, a “second” item does not require or preclude the existence of, for example, a “first” or lower-numbered item or a “third” or higher-numbered item.

In one embodiment, a computer program is provided, and the program is embodied on a computer readable medium. In the exemplary embodiment, the system is executed on a single computer system, without requiring a connection to a sever computer. In a further embodiment, the system is being run in a Windows® environment (Windows is a registered trademark of Microsoft Corporation, Redmond, Washington). In yet another embodiment, the system is run on a mainframe environment and a UNIX® server environment (UNIX is a registered trade-mark of X/Open Company Limited located in Reading, Berkshire, United Kingdom). In a further embodiment, the system is run on an iOS® environment (iOS is a registered trademark of Cisco Systems, Inc. located in San Jose, CA). In yet a further embodiment, the system is run on a Mac OS® environment (Mac OS is a registered trademark of Apple Inc. located in Cupertino, CA). In still yet a further embodiment, the system is run on Android® OS (Android is a registered trademark of Google, Inc. of Mountain View, CA). In another embodiment, the system is run on Linux® OS (Linux is a registered trademark of Linus Torvalds of Boston, MA). The application is flexible and designed to run in various different environments without compromising any major functionality. In some embodiments, the system includes multiple components distributed among a plurality of computing devices. One or more components may be in the form of computer-executable instructions embodied in a computer-readable medium.

As used herein, references to “example embodiment” or “one embodiment” of the present disclosure are not intended to be interpreted as excluding the existence of additional embodiments that also incorporate the recited features.

As used herein, the terms “software” and “firmware” are interchangeable, and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

As used herein, a processor may include any programmable system including systems using micro-controllers, reduced instruction set circuits (RISC), application specific integrated circuits (ASICs), logic circuits, and any other circuit or processor capable of executing the functions described herein. The above examples are example only, and are thus not intended to limit in any way the definition and/or meaning of the term “processor.”

The systems and processes are not limited to the specific embodiments described herein. In addition, components of each system and each process can be practiced independent and separate from other components and processes described herein. Each component and process also can be used in combination with other assembly packages and processes.

As used herein, the term “non-transitory computer-readable media” is intended to be representative of any tangible computer-based device implemented in any method or technology for short-term and long-term storage of information, such as, computer-readable instructions, data structures, program modules and sub-modules, or other data in any device. Therefore, the methods described herein may be encoded as executable instructions embodied in a tangible, non-transitory, computer readable medium, including, without limitation, a storage device and/or a memory device. Such instructions, when executed by a processor, cause the processor to perform at least a portion of the methods described herein. Moreover, as used herein, the term “non-transitory computer-readable media” includes all tangible, computer-readable media, including, without limitation, non-transitory computer storage devices, including, without limitation, volatile and nonvolatile media, and removable and non-removable media such as a firmware, physical and virtual storage, CD-ROMs, DVDs, and any other digital source such as a network or the Internet, as well as yet to be developed digital means, with the sole exception being a transitory, propagating signal.

Embodiments of the invention relate generally to systems and methods for analyzing physical features of sorbents for post combustion carbon capture (“PCC”), and more particularly, to systems and methods for modeling aspects of metal-organic frameworks (“MOFs”) based on their constituents and their performance in capture capacity for carbon dioxide (CO₂). In example embodiments, a modeling system is configured to train a model based on performance characteristics of known metal-organic frameworks (“MOFs”) and their associated constituents. This model may then be used to evaluate the anticipated performance of other MOFs based on their particular constituents. Such modeling can help scientists and engineers evaluate different MOFs without having to physically test each candidate, thus leading to the quicker development of MOFs having improved performance in capture capacity for CO₂.

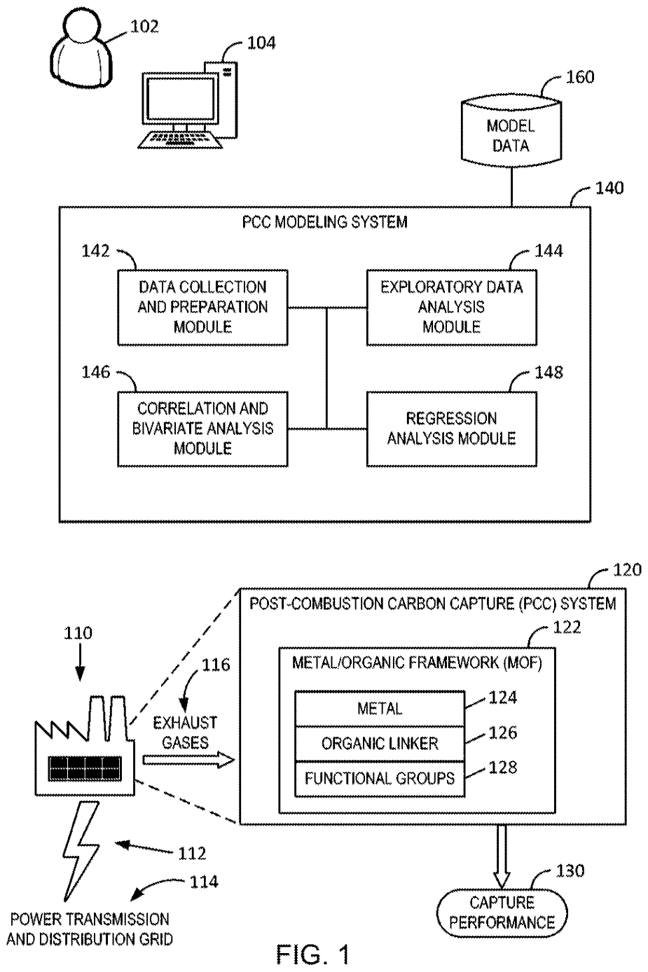

FIG. 1 illustrates an example PCC modeling system 140 that can be used to anticipate how particular MOFs may perform in capturing carbon dioxide (CO2) from exhaust gases 116 of a coal-fired power plant 110. In the example embodiment, the power plant 110 generates electricity 112 that is distributed via a power transmission and distribution grid 114. The power plant 110 also includes a post-combustion carbon capture (PCC) system 120 that is configured to remove CO₂ from the exhaust gases 116 before the treated exhaust is released into the environment. The example PCC system 120 includes a metal-organic framework (MOF) 122 that performs the capturing functionality of the PCC system 120. The MOF 122 is comprised of three primary constituents, namely a metal 124, an organic linker 126, and one or more functional groups 128. During operation, the PCC system 120 yields some performance results, represented here generally as “capture performance” 130 (e.g., PCC capacity) for purposes of discussion. The PCC modeling system 140 is configured to estimate how particular MOFs (e.g., particular combinations of constituents and various associated physical features) would perform if implemented in the PCC system 120 (e.g., performance predictions in a “real world” setting).

In the example embodiment, the PCC modeling system 140 includes a data collection and preparation module 142 that is configured to identify and store data that will be used to train a machine learning model (e.g., a supervised forecasting model). The preparation module 142 stores historical records of various sorbents (e.g., MOFs 122) and their associated features and known performance. Each historical record can include, for example, sorbent data such as the constituents of the particular sorbent (e.g., information on the metal 124 used in the secondary building unit or SBU, information on the organic linker 126, and/or information on any functional groups 128 or amines associated with the particular MOF 122), various physical features of the sorbent (e.g., pore size, pore volume, pore size distribution, surface area, and the like), and known performance data for the sorbent (e.g., isosteric heat of adsorption (Q_{ST}), Henry's Law constant, selectivity ratio, sorbent capacity in millimoles of CO₂ per gram of sorbent, sorbent productivity in millimoles of CO₂ per gram of sorbent per unit time, or the like, at a particular pressure and/or temperature). Each of these historical records may be stored as model data 160 (e.g., in a database) and may include other data described herein. Some of these records may be collected from publication literature, where other records may include data collected from laboratory measured data or operational performance data of the PCC system 120 (e.g., data collected during operation).

The PCC modeling system 140 also includes an exploratory data analysis module 144 that is configured to help an analyst 102 perform univariate data analysis on aspects of the historical data. In an example embodiment, the exploratory data analysis module 144 is configured to generate graphs that display a single constituent of known MOFs against a single feature, thereby allowing the analyst 102 to see trends for the feature across various MOFs. For example, the analysis module 144 may generate a plot of chemisorbents and physisorbents, two types of MOFs, and how they perform with regard to Henry's constant, selectivity ratio, heat of adsorption, PCC capacity, and PCC productivity (e.g., as a composite across those two types of MOFs). In another example, the analysis module 144 may generate a plot of various metal types in physisorbent or chemisorbent MOFs and their respective adsorption heat (e.g., ranges of values, average value, or the like, for each metal type). These plots may be compiled and generated from the historical records identified in the model data 160 and displayed to the analyst 102 via a display of the computing device 104. From this data, the analyst 102 may further identify one or more second order features, which may be combinations of two or more of first order features, as discussed further below. Such second order features may be used in later model training and analysis.

The PCC modeling system 140, in the example embodiment, also includes a correlation and bivariate analysis module 146 that is configured to analyze the model data 160 with respect to positive or negative correlations between the pairs of various features of the historical records. For example, the analysis module 146 may identify a set of first order features, and perhaps one or more second order features, and perform a correlation analysis between the associated features. For each particular pairing of two features, the analysis module 146 computes a correlation coefficient (e.g., across all records in the model data 160) that identifies how those two features correlate with each other (e.g., where a positive coefficient indicates a positive correlation between the two features, and where a negative coefficient indicates a negative correlation between those two features). These correlation coefficients may be, for example, Pearson's correlation coefficients or the like. These correlation coefficients may be displayed to the analyst 102 in a matrix format, thereby allowing the analyst 102 to view the strengths of correlations between the various feature pairs. In some examples, the matrix may be a heat map that, for example, displays each correlation coefficient in a color of a color spectrum having strong positive correlations in a color at one end of the spectrum (e.g., dark blue) and having strong negative correlations in another color at the opposite end of the spectrum (e.g., dark red), being colored along the spectrum based on the magnitude of the correlation coefficient. In some examples, the analysis module 146 may generate pair plots for each of the feature pairs, thereby allowing the analyst 102 to evaluate what type of relationship the two features have (e.g., linear, non-linear, or such).

The PCC modeling system 140 also includes a regression analysis module 148 that is configured to perform regression analysis using the model data 160. In the example embodiment, the regression analysis module 148 identifies one or more features of interest for regression analysis. In some embodiments, the analyst 102 may inspect the correlation matrix and/or pair plots discussed above and may select a subset of features of interest. In some embodiments, the regression analysis module 148 may automatically identify one or more features of interest for the regression analysis (e.g., based on the correlation coefficients of the matrix). For example, the regression analysis module 148 may select all features that have a positive correlation coefficient with the PCC capacity above a particular threshold (e.g., strongly positively correlated). In some embodiments, the regression analysis module 148 may also select all features that have a negative correlation coefficient with the PCC capacity that is below a particular threshold (e.g., strongly negatively correlated). In some embodiments, the features that are used to start the regression analysis are manually selected, such as by a user.

Once a subset of features are identified, the regression analysis module 148 performs a regression analysis process starting with the subset of features. In some embodiments, a portion of the model data 160 may be automatically or manually identified as training data (e.g., to be used in this regression analysis process) and the remaining portion of the model data 160 may be reserved for evaluating the resulting model (e.g., 60% training data, 40% testing data). In the example embodiment, the regression analysis process is performed in one or more stages, where each stage includes performing multiple linear regression analyses on a current set of features. Based on the results at each stage, one or more features may be removed for a subsequent stage of analysis, leaving a further subset of down-selected features for the next stage of analysis until a particular stop criterion is achieved. At this final stage, the regression analysis module 148 generates a transfer function using the final remaining down-selected feature(s) (e.g., PCC capacity as a function the particular down-selected features). This transfer function thus can be applied to a new MOF, and its associated feature values, to anticipate how that novel MOF may perform with respect to PCC capacity, productivity, or the like. Without the PCC modeling system 140 of FIG. 1, factors such as kinetics of cycle time for adsorption not allowing for equilibrium to be achieved, coating mass transfer resistance, and/or isosteric heat of adsorption heating the sorbent and reducing performance capacity may be generally experimentally determined in order to understand the final productivity of a given sorbent.

For the initial sorption at low concentration, the Henry's Law constant determines the equilibrium capacity of the sorbent. The sorbent capacity of the sorbent i, Nᵢ, is a function of the Henry's Law constant, Hᵢ, multiplied by the gas phase concentration of the sorbent, Cᵢ, as: Nᵢ=HᵢCᵢ. The larger the value of the Henry's constant, the steeper the initial slope of the isotherm. This means that a sorbent with a higher Hᵢ has a larger capacity for the sorbate in this low concentration linear region of the isotherm. Maximizing the Hᵢ also increases the productivity of the sorbent at low gas phase sorbate concentrations. As such, the PCC modeling system 140 will look to find sorbents with high Henry's Law constants for CO₂ adsorption by analyzing how the various MOF constituents independently vary with the Henry's constant. Since the Henry's constant is a thermodynamic term (e.g., not a kinetic term), the kinetics of the sorbent may also be evaluated in order to determine sorbent productivity. These measurements are not typically reported in the literature of known MOFs, and as such, this PCC modeling system 140 may look first at the Henry's constant to identify MOF constituents with the potential for the highest capacity of CO₂ at the lowest gas phase concentration of CO₂. Where kinetic uptake data are available, they are used as data inputs to the PCC modeling system.

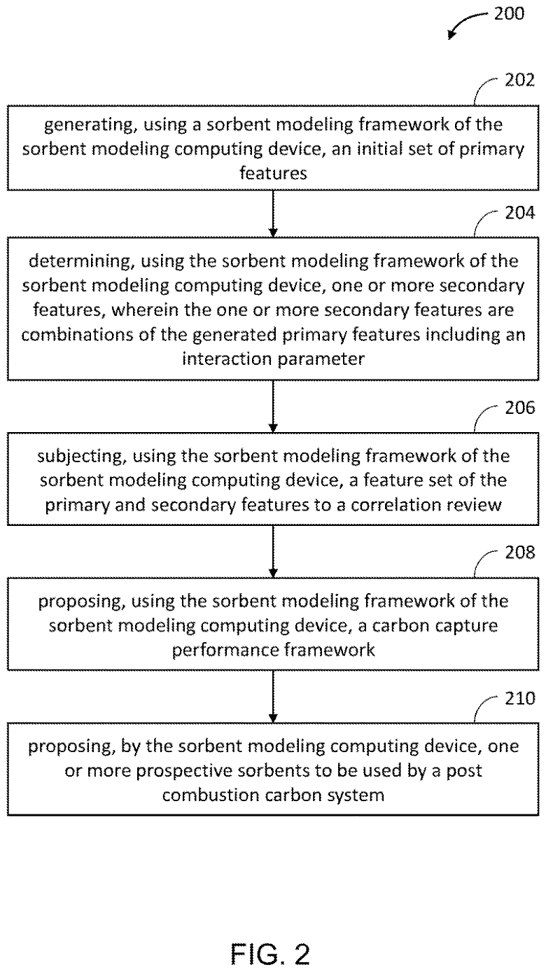

FIG. 2 is a flow chart illustrating an exemplary method 200 in accordance with the present disclosure, such as for proposing prospective sorbents for use in post-combustion carbon capture systems. The method 200 is performed using a sorbent modeling computing device that includes a processor coupled to a memory device. In the example embodiment, the method 200 includes generating 202, using a sorbent modeling framework of the sorbent modeling computing device, such as, but not limited to, PCC modeling system 140, an initial set of “primary features” (e.g., known variables, as in pre-existing main effects parameters for the historical sorbent, such as isosteric heat of adsorption, Henry's Law constant, pore size, pore volume, surface area, or the like) for known sorbents (e.g., MOFs for which there is known performance data).

For example, the data used by the modeling system may include instances of individual sorbents and their particular composures and known performance data stored in a database such as the model data database (e.g., various variables for particular known sorbents). Each sorbent may include information on constituents of that particular sorbent instance (e.g., a particular metal, organic linker, and/or functional groups or functionalities), various physical features of the sorbent instance (e.g., pore size, pore volume, isometric heat of adsorption, Henry's Law constant, selectivity ratio, Langmuir/BET area, uptake rate, or the like), known performance data for the sorbent instance (e.g., PCC capacity and productivity), and perhaps other information on the sorbent instance, such as a unique identifier or other sorbent data (e.g., physisorbent or chemisorbent classification). Metals can include, for example, nickel, chromium, magnesium, copper, manganese, zirconium, zinc, cobalt, indium, iron, aluminum, dysprosium, titanium, potassium, or the like, or some combination or alloy). Organic linkers can include, for example, 1,4-dioxido-2,5-Benzenedicarboxylate (DOBDC), 1,4-benzene-dicarboxylate (BDC), 4,4′-oxido-1,1′-biphenyl-3,3′-dicarboxylate (DOBPDC), 1,3,5-tri(1H-1,2,3-trizol-4-yl)benzene) (BTTri), 1,3,5-benzene tricarboxylate (BTC), 1H,5H-benzo(1,2-d: 4,5-d′)bistriazole (BBTA), 1,1′-Bipheny1-4,4′-dicarboxylate (BPDC), 1,1′-biphenyl-3,3′ ,5,5′-tetracarboxylate (BPTC), 1,5-dioxido-2,6-naphthalenedicarboxylate (DONDC), 1,2,4,5-benzene-tetra-carboxylate (BTEC), 1,4-bix(1H-pyrazol-4-ylethynyl)benzene (BPEP), 2,5-di(1H-1,2,4-triazol-1-yl)terephthalate (BTTA), 2,4,6-tris(3,5-dicarboxylphenylamino)-1,3,5-triazine (TDPAT), 2,3,5,6-tetrachloo terephthalate (TCDC), 4,4′-dibenzoic acid-2,2′sulfone (SBPDC), or the like. Functionalities can include, for example, Open Metal Sites [OMS], Microporosity [MP], Lewis Basic Site [LBS], Polar Functional Site [PFS], Post Synthetic Modifications [PSM], or the like. While example metals, linkers, functional groups, and physical features are provided here, it should be understood that others are possible and within the scope of this disclosure.

The data may be used by the modeling system as model training data for training a machine learning model to analyze anticipated performance of prospective sorbents (e.g., novel combinations of metals, linkers, and functionalities not already studied and tested in real-world conditions). This model training data can be used as labeled training data in model construction (e.g., instances of model training data of particular “inputs” having a known result or “label”). In some embodiments, one subset of the model training data may be identified for purposes of training the model and another subset may be identified for purposes of testing the model (e.g., 60% of sorbents being identified for training and 40% being identified for testing, 70% being identified for training and 30% being identified for testing, or the like). In some embodiments, the sorbents may be manually identified for use in training and testing (e.g., by particular rows of the database). In some embodiments, the PCC modeling system 140 may automatically identify the training subset and the testing subset (e.g., using preconfigured percentages, randomly selected, or the like).

In the example embodiment, the method 200 also includes determining 204, using the sorbent modeling framework of the sorbent modeling computing device, such as, but not limited to, PCC modeling system 140, one or more secondary features, wherein the secondary features are combinations of the generated primary features that involve an interaction between the combined primary features (e.g., an interaction parameter).

The modeling system may output a graphical user interface that displays plots of particular features against other target features of interest for trend and relation analysis between those particular features. For example, the modeling system may generate a plot of organic linkers versus isosteric heat of adsorption or Henry's Law constant or average pore size, and may separately identify physisorbents or chemisorbents (e.g., via distinct colors or shading). Additionally, for example, the modeling system may generate a plot of metals identified in the training data against isosteric heat of adsorption or a selectivity ratio.

The one or more combinations of the generated primary features may be designated as secondary features to be used by the modeling system. In one example, a secondary feature “A” may be created as (BET area*Pore Volume (Vₚₒᵣₑ)), a secondary feature “B” as (Vₚₒᵣₑ*isosteric heat of adsorption (Qₛₜ), and a secondary feature “C” as (BET area*Qₛₜ). In some embodiments, for n as the number of primary features, a number ″C of secondary features may be designated.

The modeling system may analyze the statistical significance of each of the primary features, such as via a probability value. The probability value (p-value) is a measure of the significance of a variable to the model. A p-value less than 0.05 means that the factor in the model is statistically significant with 95% confidence, which indicates strong evidence against the results being random, with less than a 5% probability that the results are random.

In the example embodiment, the method 200 also includes subjecting 206, using the sorbent modeling framework of the sorbent modeling computing device, such as, but not limited to, PCC modeling system 140, a feature set of the primary and secondary features to a correlation review. For example, this may include evaluating particular individual sorbent variables (e.g., a particular constituent or feature) relative to other variables (e.g., another constituent, feature, or performance value) across the body of training data. This analysis can be used to identify high level trends relative to the particular constituents or features. For example, the modeling system may perform correlation and bivariate analysis of the data to generate the feature set. Additionally, for example, the modeling system may generate pair plots or scatter plots for each unique combination of the primary and secondary features in the feature set for data correlation analysis. These plots may help identify whether there is any correlation between variables, whether that correlation is linear or non-linear, and whether it is a positive or negative correlation. Additionally, these plots may help identify the variables that are statistically significant.

In some embodiments, the correlation review may include a correlation matrix, such as an n by n matrix, where each unique feature in the feature set is assigned both a row and a column (e.g., a square, reflective matrix). Each cell of the matrix represents some combination of two of the features in the feature set (e.g., based on the particular row and column of that cell), and the value contained in that cell is a correlation coefficient that represents a degree or magnitude of correlation between those two particular features. For each combination of two features, the modeling system may compute a correlation coefficient for those two features (e.g., across the training data). Correlation coefficients, in the example embodiment, are normalized from a range between +1.0 and −1.0, with more positive correlations between the two features being closer to +1.0, more negative correlations being closer to −1.0, and neutral (e.g., weak or non-existent) correlations being closer to 0.0 (e.g., a Pearson's correlation coefficient). The modeling system may populates the particular cell(s) with the correlation coefficient associated with those two features. Upon completion, this correlation matrix and associated values may be analysis, such as via a heat map (e.g., coloring each individual cell based on its value), to determine positive and negative correlations between particular features.

In the example embodiment, the method 200 also includes proposing 208, using the sorbent modeling framework of the sorbent modeling computing device, such as, but not limited to, PCC modeling system 140, a carbon capture performance framework. For example, the modeling system may perform a regression analysis and generate a transfer function based on this regression analysis to approximate carbon capture performance of other (e.g., untested) sorbents.

The modeling system may identify a set of model training data as part of the regression analysis. The training data thus represents which known sorbents are within the scope of this particular regression analysis and where the remaining model data may be used to verify the results of this training. The modeling system may also select a set of features for an initial feature set. In some embodiments, all of the features of the full feature set may be initially used as the initial feature set. In other embodiments, the features in the initial feature set may be manually selected (e.g., based on reviewing the pair plots and/or correlation matrix). In still other embodiments, the modeling system may automatically select the initial feature set. For example, the modeling system may selectively add all features to the initial feature set that have a correlation coefficient with the PCC capacity above a predetermined threshold (e.g., greater than 0.2), or below a predetermined threshold (e.g., less than −0.2). A number of these features, f, are then used as a current feature set to begin the regression.

The modeling system may also perform multiple linear regressions on the model training data using the current feature set (e.g., using an ordinary least-squared model fit of the training data, where the PCC productivity is the dependent variable of interest, as determined based on PCC capacity and the CO₂ uptake rate (e.g., adsorption kinetics)) as part of the regression analysis. For example, a linear regression method is applied to Eq. 1 to study the dependence between the parameter of interest (e.g., the PCC capacity, Å) and the various physical attributes selected for the initial feature set (e.g., BET area, pore volume, isosteric heat, and the second order features “A”, “B”, and “C” described above):

Å=B₀+b₁X₁+b₂X₂+ . . . +bₚXₚ Eq. 1

In this regression, each of the ƒ current features are represented in Eq. 1 by Xᵢ, along with an associated linear coefficient bᵢ. At first, all initial features are included in the transfer function of Eq. 1 as the regression iterates, then the current feature with the highest p-value is eliminated until all current features have a p-value of less than a predetermined value (e.g., less than 0.05 meaning they have a 95% probability of being statistically significant). The relevant variables in the model are those that have a probability value (“p-value”) less than the predetermined threshold.

More specifically, at each step in the iteration, p-values are generated for each feature remaining in the set of current features. The modeling system may test whether the regression is complete by evaluating the p-values of the current features. If all of the p-values of the remaining current features are below the predetermined threshold, the iteration terminates. Otherwise, the iteration continues. The modeling system may identify the current feature having the highest p-value and remove that particular feature from the current features for the next iteration. The regression process may continue on with a reduced current feature set, again generating new p-values until all remaining features are below the predetermined threshold. If a primary feature has a p-value above the threshold, but a secondary feature that includes the primary feature has a p-value below the threshold, then the primary feature is kept as part of the model, even though it's individual p-value is larger than the threshold. This is necessary in order to keep the secondary feature with p-value below the threshold as part of the model.

Upon completion and exit of the regression iterations, the modeling system may have identified one or more remaining features to be included in a final feature set, each of which has a p-value at or below the predetermined threshold and is therefore statistically significant. The modeling system may inspect the final results for possible indications of overfitting in the model. For the final feature set, the modeling system also generates an r-squared and adjusted r-squared value, and the difference between these two values can be an indication of overfitting (e.g., if they are too far apart). If the difference between the r-squared and adjusted r-squared values (e.g., abs(r-squared—adjusted r-squared)) is greater than a predetermined threshold, then there are chances of overfitting in the model. In such situations, the modeling system may then analyze each unique combination of the remaining features in the final feature set, run the model with that combination to generate r-squared and adjusted r-squared values for each combination, and then select the particular combination that has the closest r-squared and adjusted r-squared values (e.g., the smallest abs(r-squared—adjusted r-squared)).

Based on this regression analysis, the modeling system may generate the transfer function to approximate carbon capture performance of other (e.g., untested) sorbents. More specifically, the regression yields a final coefficient for each of the remaining features in the final feature set, as well as a constant coefficient (e.g., y-intercept value). As such, each of the X_{ƒ} variables of Eq. 1 are identified with each of the remaining features, and each associated coefficient b_{ƒ} is added into Eq. 1, as well as the constant coefficient b₀, to generate the final transfer function. As such, this transfer function can be used with prospective sorbents and their associated values to determine an anticipated PCC capacity of that particular sorbent.

The modeling system may use the model on test data to evaluate how it performs in predictive capability. For example, the modeling system may generate a residual plot for the linear regression model for both the training data and the test data for an evaluation of how well the model performs.

For example, a regression operation may be performed on an example training set starting with an initial feature set of isosteric heat of adsorption (Qₛₜ), BET area, Pore Volume (Vₚₒᵣₑ)), and the three example secondary features “A”, “B”, and “C”. At a first iteration, the p-value of BET area is identified as the highest at 0.948 and is removed. At a second iteration, the p-value of the “A” secondary feature is identified as the highest at 0.769 and is removed. At a third iteration, the p-value of the “B” secondary feature is identified as the highest at 0.441 and is removed. At a fourth iteration, the p-values of all of the remaining current features (e.g., Qₛₜ, Vₚₒᵣₑ, and the “C” secondary feature) are below 0.05, and thus the regression iteration terminates with these three features as the final feature set. However, in this example, the final r-squared value is 0.400 and the adjusted r-squared value is 0.363, a difference which triggers analysis for overfitting. Since there are three remaining features in the final feature set 384, each combination of those features is inspected with the model (e.g., a total of 3!=6 unique combinations, namely [Qₛₜ], [Qₛₜ, Vₚₒᵣₑ], [Qₛₜ, Vₚₒᵣₑ, “C”], [Vₚₒᵣₑ], [Vₚₒᵣₑ, “C”], and [“C”]). In this example, the combination of just [Qₛₜ] yields an r-squared of 0.567 and an adjusted r-squared of 0.560, for the smallest difference of 0.007. As such, only the Qₛₜ feature and its associated values are used to generate the final transfer function with only the one remaining feature (e.g., X1=Qₛₜ), namely Å=b₁X₁+b₀=0.0318*Qₛₜ−0.4243, where b₁=0.0318 is the final coefficient generated for Qₛₜ and where b₀=−0.4243 is the constant coefficient. Applying test data to the trained model, in this particular example, yielded a test r-squared value of 0.331, where the r-squared of the trained model was 0.567. As such, the equation includes only features for which the p-value is less than 0.05. Further, the positive r-square of the test data is indicates that the model is able to explain about 60% of the capacity using the heat of adsorption (Qₛₜ).

In the example embodiment, the method 200 further includes proposing 210, by the sorbent modeling computing device, one or more prospective sorbents to be used by the post combustion carbon system. For example, the modeling system may identify one or more prospective sorbents based on the carbon capture performance value as determined by the transfer function to facilitate improving the overall carbon capture performance of the post combustion carbon capture system.

The methods, systems, and compositions disclosed herein are not limited to the specific embodiments described herein, but rather, steps of the methods, elements of the systems, and/or elements of the compositions may be utilized independently and separately from other steps and/or elements described herein.

Although specific features of various embodiments may be shown in some drawings and not in others, this is for convenience only. Moreover, references to “one embodiment” in the above description are not intended to be interpreted as excluding the existence of additional embodiments that also incorporate the recited features. In accordance with the principles of the disclosure, any feature of a drawing may be referenced and/or claimed in combination with any feature of any other drawing.

This written description uses examples, including the best mode, to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

Further aspects of the invention are provided by the subject matter of the following clauses:

A method of proposing one or more prospective sorbents, the method performed using a sorbent modeling computing device that includes a processor coupled to a memory device, the method comprising: generating, using a sorbent modeling framework of the sorbent modeling computing device, an initial set of primary features; determining, using the sorbent modeling framework of the sorbent modeling computing device, one or more secondary features, wherein the one or more secondary features are combinations of the generated primary features including an interaction parameter; subjecting, using the sorbent modeling framework of the sorbent modeling computing device, a feature set of the primary and secondary features to a correlation review; proposing, using the sorbent modeling framework of the sorbent modeling computing device, a carbon capture performance framework; and proposing, by the sorbent modeling computing device, one or more prospective sorbents to be used by a post combustion carbon system.

The method in accordance with any of the preceding clauses, wherein generating the initial set of primary features comprises generating one or more sorbent parameters for known sorbents.

The method in accordance with any of the preceding clauses, wherein generating the one or more sorbent parameters for known sorbents comprises generating one or more of an isosteric heat of adsorption, a Henry's Law constant, a pore size, a pore volume, and a surface area.

The method in accordance with any of the preceding clauses, wherein proposing the one or more prospective sorbents comprises proposing one or more metal-organic frameworks.

The method in accordance with any of the preceding clauses, wherein determining the interaction parameter comprises determining at least one of a correlation coefficient and a statistical significance.

The method in accordance with any of the preceding clauses, wherein subjecting the feature set to the correlation review comprises generating a pair plot or a scatter plot.

The method in accordance with any of the preceding clauses, wherein subjecting the feature set to the correlation review comprises generating a correlation matrix.

The method in accordance with any of the preceding clauses, wherein proposing the carbon capture performance framework comprises conducting a regression analysis and generating a transfer function generated based on the regression analysis.

The method in accordance with any of the preceding clauses, wherein proposing the one or more prospective sorbents is based on a carbon capture performance value as determined by the carbon capture performance framework.

The method in accordance with any of the preceding clauses, wherein proposing the one or more prospective sorbents comprises the carbon capture performance value being determined using the transfer function generated based on the regression analysis.

A sorbent modeling computing device comprising: a memory; and a processor communicatively coupled to the memory, the processor programmed to: generate an initial set of primary features with a sorbent modeling framework; determine one or more secondary features with the sorbent modeling framework, wherein the one or more secondary features are combinations of the generated primary features including an interaction parameter; subject a feature set of the primary and secondary features to a correlation review with the sorbent modeling framework; propose a carbon capture performance framework with the sorbent modeling framework; and propose one or more prospective sorbents to be used by a post combustion carbon system.

The sorbent modeling computing device in accordance with any of the preceding clauses, wherein the initial set of primary features comprises one or more sorbent parameters for known sorbents.

The sorbent modeling computing device in accordance with any of the preceding clauses, wherein the one or more sorbent parameters for known sorbents includes one or more of an isosteric heat of adsorption, a Henry's Law constant, a pore size, a pore volume, and a surface area.

The sorbent modeling computing device in accordance with any of the preceding clauses, wherein the proposal of the one or more prospective sorbents comprises one or more metal-organic frameworks.

The sorbent modeling computing device in accordance with any of the preceding clauses, wherein the interaction parameter comprises at least one of a correlation coefficient and a statistical significance.

The sorbent modeling computing device in accordance with any of the preceding clauses, wherein the correlation review comprises generating a pair plot or a scatter plot.

The sorbent modeling computing device in accordance with any of the preceding clauses, wherein the correlation review comprises generating a correlation matrix.

The sorbent modeling computing device in accordance with any of the preceding clauses, wherein the carbon capture performance framework comprises a regression analysis and a transfer function generated based on the regression analysis.

The sorbent modeling computing device in accordance with any of the preceding clauses, wherein the proposal of the one or more prospective sorbents is based on a carbon capture performance value as determined by the carbon capture performance framework.

The sorbent modeling computing device in accordance with any of the preceding clauses, wherein the carbon capture performance value is determined using the transfer function generated based on the regression analysis.

While the invention has been described in terms of various specific embodiments, those skilled in the art will recognize that the invention can be practiced with modification within the spirit and scope of the claims.

1. A method of proposing one or more prospective sorbents, the method performed using a sorbent modeling computing device that includes a processor coupled to a memory device, the method comprising:
generating, using a sorbent modeling framework of the sorbent modeling computing device, an initial set of primary features;
determining, using the sorbent modeling framework of the sorbent modeling computing device, one or more secondary features, wherein the one or more secondary features are combinations of the generated primary features including an interaction parameter;
subjecting, using the sorbent modeling framework of the sorbent modeling computing device, a feature set of the primary and secondary features to a correlation review;
proposing, using the sorbent modeling framework of the sorbent modeling computing device, a carbon capture performance framework; and
proposing, by the sorbent modeling computing device, one or more prospective sorbents to be used by a post combustion carbon system.

2. The method in accordance with claim 1, wherein generating the initial set of primary features comprises generating one or more sorbent parameters for known sorbents.

3. The method in accordance with claim 2, wherein generating the one or more sorbent parameters for known sorbents comprises generating one or more of an isosteric heat of adsorption, a Henry's Law constant, a pore size, a pore volume, and a surface area.

4. The method in accordance with claim 1, wherein proposing the one or more prospective sorbents comprises proposing one or more metal-organic frameworks.

5. The method in accordance with claim 1, wherein determining the interaction parameter comprises determining at least one of a correlation coefficient and a statistical significance.

6. The method in accordance with claim 1, wherein subjecting the feature set to the correlation review comprises generating a pair plot or a scatter plot.

7. The method in accordance with claim 1, wherein subjecting the feature set to the correlation review comprises generating a correlation matrix.

8. (canceled)

9. The method in accordance with claim 81, wherein proposing the one or more prospective sorbents is based on a carbon capture performance value as determined by the carbon capture performance framework.

10. The method in accordance with claim 9, wherein proposing the one or more prospective sorbents comprises the carbon capture performance value being determined using the transfer function generated based on the regression analysis.

11. A sorbent modeling computing device comprising:
a memory; and
a processor communicatively coupled to the memory, the processor programmed to:
generate an initial set of primary features with a sorbent modeling framework;
determine one or more secondary features with the sorbent modeling framework, wherein the one or more secondary features are combinations of the generated primary features including an interaction parameter;
subject a feature set of the primary and secondary features to a correlation review with the sorbent modeling framework;
propose a carbon capture performance framework with the sorbent modeling framework; and
propose one or more prospective sorbents to be used by a post combustion carbon system.

12. The sorbent modeling computing device in accordance with claim 11, wherein the initial set of primary features comprises one or more sorbent parameters for known sorbents.

13. The sorbent modeling computing device in accordance with claim 12, wherein the one or more sorbent parameters for known sorbents includes one or more of an isosteric heat of adsorption, a Henry's Law constant, a pore size, a pore volume, and a surface area.

14. The sorbent modeling computing device in accordance with claim 11, wherein the proposal of the one or more prospective sorbents comprises one or more metal-organic frameworks.

15. The sorbent modeling computing device in accordance with claim 11, wherein the interaction parameter comprises at least one of a correlation coefficient and a statistical significance.

16. The sorbent modeling computing device in accordance with claim 11, wherein the correlation review comprises generating a pair plot or a scatter plot.

17. The sorbent modeling computing device in accordance with claim 11, wherein the correlation review comprises generating a correlation matrix.

18. (canceled)

19. The sorbent modeling computing device in accordance with claim 11, wherein the proposal of the one or more prospective sorbents is based on a carbon capture performance value as determined by the carbon capture performance framework.

20. The sorbent modeling computing device in accordance with claim 19, wherein the carbon capture performance value is determined using the transfer function generated based on the regression analysis.
